(19) United States
(12) Patent Application Publication
(10) Pub. No.: US 2011/0032127 A1
(43) Pub. Date: Feb. 10, 2011

(54) Low touch-force fabric keyboard

(76) Inventor: Jeffrey M. Roush, Davis, CA (US)

Correspondence Address: MARK RODGERS, 1590 SAN ROQUE ROAD, SANTA BARBARA, CA, 93105, US

(21) Appl. No.: 12/462,689

(22) Filed: Aug. 7, 2009

(51) Int. Cl. H03K 17/94

(52) U.S. Cl. 341/34

(57) ABSTRACT

A very low touch force keyboard, employing soft conductors, preferably conductive fabric, disposed in a keyboard grid. The grid rests upon a soft substrate, and has soft spacers separating the two axes of the grid, arranged to allow conducting portions of the grid to contact each other when soft, fabric-like keys are pushed. The grid conductors are electrically connected to a keyboard controller.

### RELATED APPLICATIONS

Not Applicable

### FEDERALLY SPONSORED RESEARCH

Not Applicable

### SEQUENCE LISTING

Not Applicable

### BACKGROUND OF THE INVENTION

This invention relates to low touch-force keyboards, such as computer keyboards, and specifically to a keyboard of substantially fabric, construction or construction from materials with fabric-like properties.

People such as software programmers and writers may spend many hours a day at a computer keyboard. The various over-use injuries that can result from this activity are well-known and a variety of means exist to attempt to ameliorate the problems. Most of the corrective means center around providing cushioning for the wrists and arms, or alternative keyboard layouts that change the geometry of typing. For some individuals these means are effective but for many, alternative keyboard designs negatively impact productivity, and the cushioning available doesn't solve all problems, such as hand and finger fatigue.

For a more general solution than currently available, it is desirable to add to current solutions a significant reduction in hand and finger interaction force with the keyboard, both in terms of push force on keys, and abrasive forces on the fingers. It is the object of this invention to provide a keyboard with very little touch force and very gentle finger-key interaction

### BRIEF SUMMARY OF THE INVENTION

The invention is a soft-touch keyboard, made from two sets of flexible conductors arranged in a keyboard 2-axis grid, and a soft substrate. The keyboard uses a soft, flexible spacing layer to separate one grid from another vertically, with the spacers configured to allow contact between the two axes at key locations. Soft, flexible keys are used at the key locations for the particular keyboard type, and electrical connections connect the grid conductors to a keyboard controller.

In particular embodiments conductors are conductive stretchable fabric and the conductors are woven into at least one of an upper and lower fabric layer.

In another embodiment the keys are wrapped in fabric. In another embodiment, the keys are covered by a fabric layer.

In various embodiments, the spacing layer may be composed of individual spacers, longitudinal spacers, a layer with openings above the key contact points, or any combination of these.

### BRIEF DESCRIPTION OF THE DRAWINGS

The invention will be better understood by referring to the following figures.

FIG. 1 shows a first embodiment of the novel keyboard

FIG. 2 shows an alternative to the embodiment of FIG. 1

FIG. 3 shows a preferred embodiment of the keyboard

### DETAILED DESCRIPTION OF THE INVENTION

The invention is a keyboard whose elements are composed of soft, fabric or fabric-like material in a novel fashion, to achieve ultra-low force, both push and abrasion forces, on hands and fingers.

Fabric keyboards exist and are available commercially. These keyboards are designed to fold or roll, and are intended to act as a case for PDA.'s, smart phones and the like, providing a larger keyboard for the device when rolled out, and convenient storage, as the device case, when not in use. These keyboards are optimized for fold-ability and do not achieve particularly benign hand-finger interaction. The inventor is unaware of the use of fabric to achieve low force/abrasion in keyboard design. In addition, touch-sensitive keyboard also exist, and are also available commercially. However, even though these require no force to activate their keys, they consist of hard, unmoving surfaces. Tapping fingers for extended periods against hard, unyielding surfaces can result in significant injury.

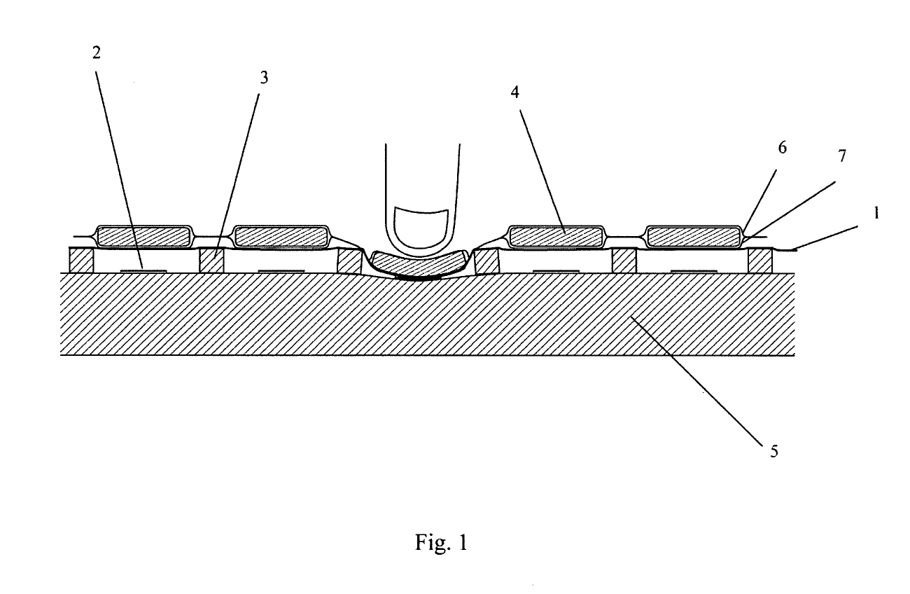

One embodiment of the invention is shown in FIG. 1. One of several horizontal keyboard grid conductors is shown at 1 and a few corresponding vertical conductors are shown at 2. Such a keyboard grid, connected to keyboard controller is known in the art. A keystroke requires that the two axes of the grid are connected substantially only at the point under the key when the key is pushed, and the keyboard controller does the rest. The invention, through the use of suitable materials and arrangement, accomplishes that connection with very little force interaction with the fingers.

Although more layers may be employed, a soft bottom substrate 5 is preferably present. An example bottom layer is a fabric covered foam piece, a little larger than the keyboard dimensions and some fraction of an inch thick. One set of conductors 2 are attached above the substrate. Soft insulating spacers 3 separate the second conductor grid layer 1 from the first grid layer 2. The spacers are disposed such that there is no insulation at the points where the two grids cross. Soft keys 4 are placed above the top grid layer 2. The materials and spacing are chosen such that a very small amount of force are needed to cause the grid conductors to meet under the key when pushed.

The inventor has produced a working prototype of the novel keyboard. Conducting materials with suitable properties for the conductors 1 and 2 in the soft keyboard are not common. The inventor used “Stretch Conductive Fabric”, a conductive fabric similar to lycra, provided by Less EMF Inc. of Albany, N.Y., which is medical grade Silver plated 92% Nylon 8% Dorlastan fabric. A small number of metal infused stretchable fabrics exist as well. The stretchable nature of the materials used is important to provide a tactile response when a key is pushed while maintaining overall low force. For the spacers, the inventor used cotton batting, sold as filler for making quilts. A particular batting, Hobbs Heirloom Premium, is 80% cotton and 20% polyester. The spacer material needs to be soft and a consistent thickness. Most soft batting fabrics are too coarse—the spacing between the fibers is large compared to the dimensions needed. The key pads were also made from this batting material. Soft foam rubber may also be acceptable for spacer, and/or key pads. In the prototype the spacers are strips ⅛″ wide and 6″ long, so consistency was important. However, the inventor has also contemplated using individual spacers placed at appropriate locations, a spacing layer with openings above the key contacts, or any combination of the above.

Again additional layers may be employed for appearance or utility, as long as the conductors can cross with no insulation at the contact points. For instance in the embodiment shown in FIG. 1, the keys 4 are wrapped between two layers, fabric layers 6 and 7 which cover the conductors and spacers. These covering layers are not used in the prototype, but most soft stretchable thin knits would be acceptable.

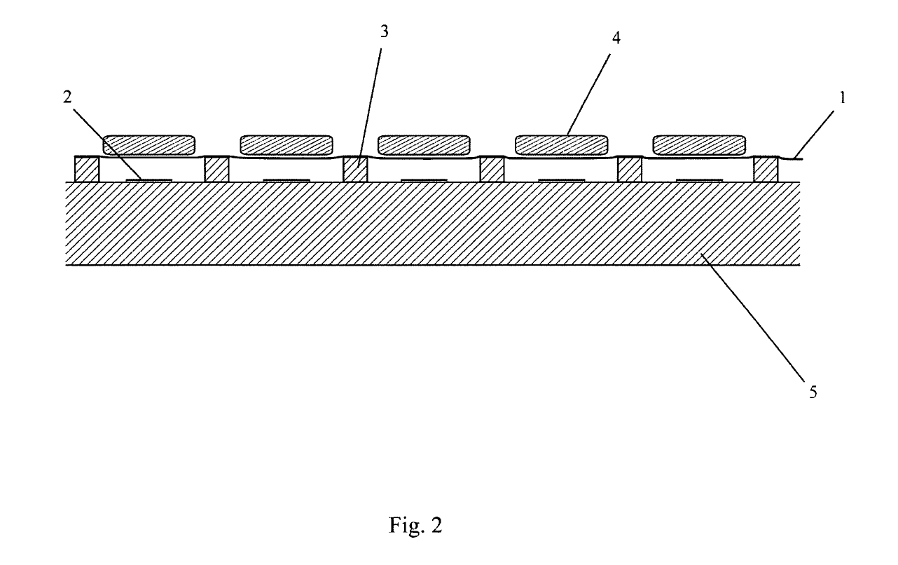

An alternative arrangement, representing the working prototype is shown in FIG. 2, where no top layer covers the keys 4.

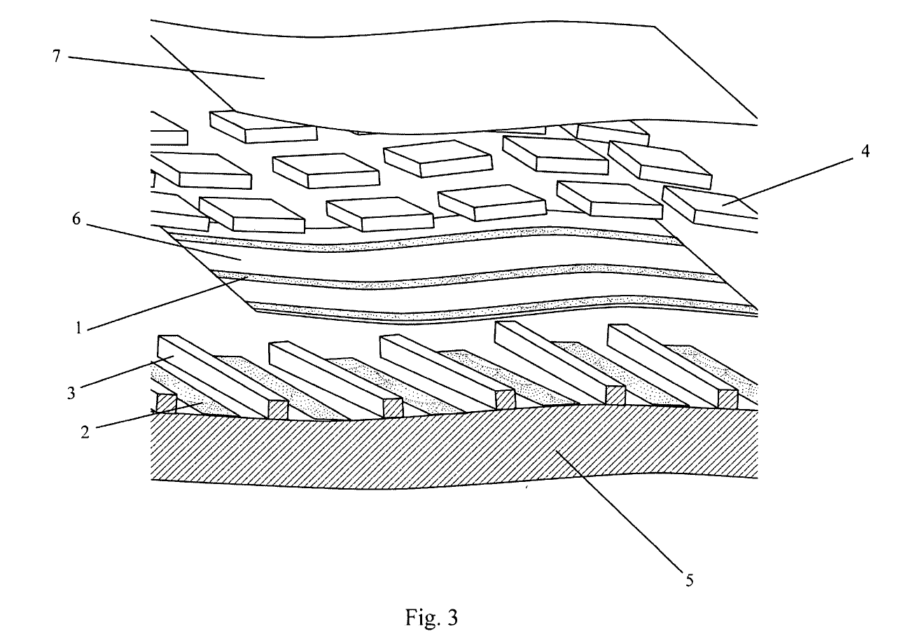

A preferred embodiment is shown in FIG. 3. In this embodiment either or both conductors 1 and 2 are preferably sewn or adhesively attached to fabric layers 5 and 6, out of conductive strips of a suitable material such as the one disclosed. Preferably a grid of spacers 3 is disposed between the layers. Keys 4 in this embodiment could easily just be printed on layer 6 or on a cover layer 7 instead of attached as separate items, although the inventor prefers an actual raised key for tactile reasons. In all embodiments, conducting grids are wired to a keyboard controller. A variety of ways to accomplish the connection will be apparent to one skilled in the art.

I claim:

1. A soft-touch keyboard, comprising;
two sets of flexible conductors arranged in a keyboard 2-axis grid, disposed over a soft substrate,
a soft, flexible spacing layer separating one grid from another vertically, and disposed to allow contact between the two axes at key locations,
soft, flexible keys disposed at the key locations for the particular keyboard type; and,
electrical connections from the grid conductors to a keyboard controller.

2. The keyboard of claim 1 wherein the conductors are conductive stretchable fabric.

3. The keyboard of claim 1 wherein the conductors are attached to at least one of an upper and lower fabric layer.

4. The keyboard of claim 1 wherein the keys are wrapped in fabric.

5. The keyboard wherein the keys are covered by a fabric layer.

6. The spacing layer of claim 1 wherein the spacing layer is at least one of individual spacers, longitudinal strips, or a solid layer with openings above the key locations.
